(19) United States
(12) Patent Application Publication
(10) Pub. No.: US 2006/0154467 A1
(43) Pub. Date: Jul. 13, 2006

(54) Method for the production of a memory cell, memory cell and memory cell arrangement

(76) Inventors: Franz Hoffman, Munchen (DE); Franz Kreupl, Munchen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 10/537,534

(22) PCT Filed: Nov. 27, 2003
(86) PCT No.: PCT/DE03/03935

§ 371 Date: Nov. 7, 2005

(30) Foreign Application Priority Data
Dec. 3, 2002 (DE) 10256486.8

(51) Int. Cl. H01L 21/20; H01L 21/44

(52) U.S. Cl. 438/611; 438/385

(57) ABSTRACT

The invention relates to a method for the production of a memory cell, a memory cell and a memory cell arrangement. According to the inventive method for the production of a memory cell, a first electrically conductive area is formed in and/or on a substrate. A second electrically conductive area is also formed at a given distance from the first electrically conductive area such that a cavity is formed between the first and second electrically conductive areas. The first and second electrically conductive areas are configured in such a way that when a first voltage is applied to the electrically conductive areas, a structure is formed from material from at least one of said electrically conductive areas, at least partically bridging over the distance between the electrically conductive areas. When a second voltage is applied to the conductive areas, the material of the structure at least partically bridging over the distance between the electrically conductive areas recedes.

### FIELD OF THE INVENTION

The invention relates to a method for producing a memory cell, to a memory cell and to a memory cell arrangement.

### BACKGROUND

In view of the rapid development in computer technology, there is a continued demand for increasingly denser and inexpensive storage media.

From the prior art, a DRAM (“Dynamic Random Access Memory”) memory cell is known in which information is coded in the state of charge of a capacitor. A DRAM has the drawback of poor scalability. In addition, a DRAM memory needs to be repeatedly refreshed, which is a drawback in terms of the power balance. Furthermore, stored information is lost from a DRAM when the power supply is disconnected.

In the case of the SRAM (“Static Random Access Memory”) memory cell, a multiplicity of transistors are connected together to store information. An SRAM has poor scalability, and stored information is lost when the power supply is disconnected.

An MRAM (“Magnetic Random Access Memory”) memory cell is also known from the prior art. In the case of this memory cell, information which is to be stored is clearly stored in the state of magnetization of a magnetizable region, with the electrical conductivity of an MRAM memory being dependent on the state of magnetization of the magnetizable region. However, with continued scaling of an MRAM, problems arise with the phenomenon of superparamagnetism. The superparamagnetic limit means that MRAM memories have only poor scalability. In addition, only a small signal can be measured between the two memory states. Furthermore, difficulties arise when reading an MRAM memory cell arrangement, and reading normally requires the provision of complex diodes.

An FeRAM memory cell is a modification of a DRAM memory cell in which the capacitor dielectric used is a ferroelectric layer. An FeRAM also has poor scalability and can be produced only with a high level of complexity.

Other memory cells known from the prior art are an EEPROM (“Electrically Erasable and Programmable Read Only Memory”) and an NROM (“Nitrided Read Only Memory”). The two memory cells have only poor scalability, and high reading and programming voltages are required.

Most of the known memory cells are based on the introduction of electrons into a memory area. However, electrons tend to equalize the charge and therefore to flow out of the memory area, which means that memory information may be lost. Hence, sufficiently long retention times can be achieved only with difficulty with such memory cells.

Terabe, K. et al. (2001) “Quantum point contact switch realized by solid electrochemical reaction”, RIKEN Review, Focused on Nanotechnology in RIKENI, No. 37, pages 7-8 describes an experiment in which a tunnel microscope (“Scanning Tunneling Microscope”, STN) is used to bring a silver sulfide tip within a few nanometers of a platinum substrate, and a suitable voltage is applied between the silver sulfide tip and the platinum substrate in order to form a quantum point contact between the silver sulfide tip and the platinum substrate.

This experiment is described below with reference to FIG. 1A and FIG. 1B.

The first experimentation arrangement 100 shown in FIG. 1A contains a platinum substrate 101 which is arranged at a distance of a few nanometers from a silver sulfide tip 102 using a tunnel microscope. As shown in the first experimentation arrangement 100, applying a first voltage 103 between the platinum substrate 101 and the silver sulfide tip 102 with an arithmetic sign which is such that the substrate 101 is negatively charged with respect to the silver sulfide tip 102 results in silver atoms leaving the silver sulfide tip, which forms a quantum point contact 104 made of silver material. The electrochemical reactions taking place in this process are likewise shown in FIG. 1A. Atomic silver material from the silver sulfide tip 102 is ionized to form positively charged silver ions on account of the arithmetic sign of the first voltage 103, whereas positively charged silver ions on the quantum tunnel contact between the platinum substrate 101 and the silver sulfide tip 102 are reduced to form elemental silver. This results in the tunnel barrier between the platinum substrate 101 and the silver sulfide tip 102 being bridged.

The text below refers to the second experimentation arrangement 110 from FIG. 1B to explain what happens when a second voltage 111 is applied between components 101, 102, with the second voltage 111 having the opposite polarity from the first voltage 103. In this operating state, the atomic silver of the quantum point contact 104 is ionized to form positively charged silver, which means that the quantum point contact 104 is taken back and there is no longer any electrical contact between the platinum substrate 101 and the silver sulfide tip 102. Ionized silver from the silver sulfide tip 102 on the negative pole of the voltage source for producing the second voltage 111 is reduced to form atomic silver.

The formation of the quantum point contact 104 to bridge the components 101, 102 alters the electrical resistance of the arrangement comprising components 101, 102, as FIG. 2 shows.

FIG. 2 illustrates a graph 200 along whose abscissa 201 an electrical voltage applied between the platinum substrate 101 and the silver sulfide tip 102 is plotted. Along the ordinate 202, the value of the measured nonreactive resistance is plotted logarithmically. In a scenario which corresponds to the first experimentation arrangement 100, electrically conductive contact exists between the platinum substrate 101 and the silver sulfide tip 102, which means that the arrangement comprising components 101, 102 has a low value for the nonreactive resistance. In a scenario which corresponds to the second experimentation arrangement 110, the quantum point contact 104 has been taken back, which means that the platinum substrate 101 is electrically decoupled from the silver sulfide tip 102, and the arrangement comprising components 101, 102 has a low value for the nonreactive resistance. In the latter state, only a small tunnel current can flow between components 102 and 102.

Haag, R. et al. (1999) “Electrical Breakdown of Aliphatic and Aromatic Self-Assembled Monolayers Used as Nanometer-Thick Organic Dielectrics”, J Am Chem Soc 121:7895-7906 discloses that aliphatic and aromatic self-assembled monolayers can be used as organic dielectrics between two components which are intended to be arranged at a distance of a few nanometers from one another.

Hofmann, F. et al. (2001) “Surrounding Gate Selector Transistor for 4F² Stacked Gbit DRAM”, ESSDERV European Solid State Device Research Conference, September 2001, discloses a vertical transistor for a DRAM memory cell.

U.S. Pat. No. 5,761,115 (Kozicki et al.), U.S. Pat. No. 5,914,893 (Kozicki et al.), U.S. Pat. No. 5,896,312 (Kozicki et al.), U.S. Pat. No. 6,084,796 (Kozicki et al.), U.S. Pat. No. 6,348,365 (Moore et al.); U.S. Pat. No. 6,391,688 (Gonzalez et al.), and U.S. Pat. No. 6,418,049 (Kozicki et al.) disclose memories in which a chalcogenide is arranged between a first electrode and a second electrode. The application of an electrical voltage between the two electrodes allows a dendrite to grow or regress through the chalcogenide.

However, a drawback of the memory cells known from U.S. Pat. No. 5,761,115 (Kozicki et al.), U.S. Pat. No. 5,914,893 (Kozicki et al.), U.S. Pat. No. 5,896,312 (Kozicki et al.), U.S. Pat. No. 6,084,796 (Kozicki et al.), U.S. Pat. No. 6,348,365 (Moore et al.); U.S. Pat. No. 6,391,688 (Gonzalez et al.), and U.S. Pat. No. 6,418,049 (Kozicki et al.) is that a sufficiently high on/off ratio for the memory cells can be achieved only using a large volume of material. In addition, the growth of the dendrite through the chalcogenide material means that it is not possible to achieve a sufficiently fast reading time and writing time for the memory cells.

U.S. Patent Application Publication No. 2002/0168820A1 (Kozicki et al.) discloses a microelectronic programmable apparatus and a method for forming and programming said apparatus.

Kohlrausch, F. (1985) “Praktische Physik” [Practical Physics], vol. 2, 23rd edition, Teubner Verlag Stuttgart, pages 31-32, discloses electrochemically current sources, particularly lead storage batteries.

For these and other reasons there is a need for the present invention.

### SUMMARY

In one embodiment the method for producing a memory cell involves a first electrically conductive region being produced in or on a substrate. In addition, a second electrically conductive region is produced at a prescribed distance from the first electrically conductive region such that a cavity is formed between the first and second electrically conductive regions. The first and second electrically conductive regions are set up such that upon application of a first voltage to the electrically conductive regions a structure which at least partially bridges the distance between the electrically conductive regions is formed from material from at least one of the electrically conductive regions. In addition, the first and second electrically conductive regions are set up such that upon application of a second voltage to the electrically conductive regions material from a structure which at least partially bridges the distance between the electrically conductive regions is taken back.

The inventive memory cell has a substrate and a first electrically conductive region produced in or on the substrate. In addition, the memory cell contains a second electrically conductive region which is arranged at a prescribable distance from the first electrically conductive region such that a cavity is formed between the first and second electrically conductive regions. The first and the second electrically conductive region are set up such that upon application of a first voltage to the electrically conductive regions a structure which at least partially bridges the distance between the electrically conductive regions is formed from material from at least one of the electrically conductive regions. The first and the second electrically conductive region are also set up such that upon application of a second voltage to the electrically conductive regions material from a structure which at least partially bridges the distance between the electrically conductive regions is taken back.

In addition, the invention provides a memory cell arrangement having a plurality of memory cells with the features described above.

A basic idea of the invention can be seen in that a memory cell is provided which can store information by virtue of a first and a second electrically conductive region jointly having either a high-resistance structure (for example information with the logic value “1”) or a low-resistance structure (for example information with a logic value “0”), the memory cell being able to be switched reversibly between the two states. If the two electrically conductive regions are arranged at the prescribed tunnel spacing from one another, which is formed by means of the defined cavity, only a small tunnel current can flow between the two electrically conductive regions, and the memory cell assumes a high value for the nonreactive resistance. If a structure which bridges the electrically conductive regions is formed between the two electrically conductive regions, however, the arrangement has a significantly lower resistance.

In line with the invention, the bridging structure between the electrically conductive regions is formed or taken back over the cavity which is produced. The growth or regression of the bridging structure can thus be achieved at a much higher rate or at lower electrical reading/writing voltages than in the case of the memory cells described in U.S. Pat. No. 5,761,115 (Kozicki et al.), U.S. Pat. No. 5,914,893 (Kozicki et al.), U.S. Pat. No. 5,896,312 (Kozicki et al.), U.S. Pat. No. 6,084,796 (Kozicki et al.), U.S. Pat. No. 6,348,365 (Moore et al.); U.S. Pat. No. 6,391,688 (Gonzalez et al.), and U.S. Pat. No. 6,418,049 (Kozicki et al.), in which a dendrite needs to grow through a solid-state layer. The invention thus allows a much shorter reading and writing time.

Unlike many memory cells known from the prior art (e.g. DRAMs, SRAMs, FeRAMs, EEPROMs, NROMs etc.), the inventive memory cell is not based on the storage of slightly volatile electrical charge carriers, but rather on forming or taking back a solid-state structure to bridge the cavity between the electrically conductive regions, which clearly corresponds more to a mechanical relay on the nanometer scale. The memory information is thus stored much more securely in the inventive memory cell, which results in a high retention time.

In addition, with a continued increase in the scale of integration for memory cells, a memory cell in which the memory information is stored in the form of electrically charge carriers is subject to fundamental physical problems. The long range of the Coulomb interactions means that charge carriers in adjacent memory cells, for example, can interact in unwanted fashion, which means that the memory information may be lost or manipulated in unwanted fashion. By contrast, the inventive memory cell is a scalable memory cell whose principle is not based on storing charge carriers, which avoids the unwanted interaction effects discussed above.

Since the cavity between the two electrically conductive regions can be reduced into the angstrom range and below (can clearly be produced as a quantum point contact), the inventive memory cell arrangement can be realized with a storage density of 60 terabits per square inch and more in the case of a simple planar arrangement. If the inventive memory cells are stacked in three dimensions above one another, which is possible on account of the layer architecture chosen, then the storage density can be increased into the pentabit range and above.

The inventive memory cell also has the advantages that it is possible to write to it and read from it with short times and small voltages, can be written to a plurality of times, is nonvolatile and can be operated under low power and low voltage demands. Thus, a supply voltage of approximately 100 mV may be sufficient for the inventive memory cell.

The use of a vacuum cavity (or a cavity filled merely with gas) achieves a particularly high on/off ratio for the nonreactive resistance values in the two operating states of the memory cell (bridging structure grown/bridging structure regressed). The use of a tunnel contact allows an exponential characteristic and thus a high level of reliability for the stored information.

A core aspect of the invention may thus be seen in the provision of a cavity produced between two electrode regions without solid or liquid filling material (apart from possible residual gas in the cavity), whose tunnel spacing, preferably in the range of one nanometer, can be changed up to a quantum point contact i.e. full bridging of the cavity (for example using moving ions in a solid-state electrolyte).

A multiplicity of such tunnel contacts, which each form a memory cell, may be used to construct a memory cell arrangement (in similar fashion to an MRAM). To read stored information, it is possible to resort to the reading principles of an MRAM, for example. Below each memory cell in a memory cell arrangement, there may also be a selection transistor or another selection element which can be actuated by means of word lines and bit lines and thus permits targeted reading of a particular memory cell. In a crossover region between two interconnects which are arranged at right angles to one another, for example, it is possible to induce a solid-state reaction, as described above with reference to FIG. 1A and FIG. 1B.

It is thus possible for two electrodes, for example one made of silver sulfide (Ag₂S) and the other made of platinum or gold, to be arranged at a distance of typically between 0.5 nm and 5 nm from one another, as a result of which the two electrodes can interact with one another through a material-free (vacuum) tunnel barrier. If an electrical potential which is negative with respect to the silver sulfide electrode is applied to the platinum electrode, then electrodes can tunnel through the tunnel spacing and can neutralize silver ions in the Ag₂S electrode to form elemental silver, which silver is then deposited on the surface of the silver sulfide electrode and forms one or more quantum point contacts. If the voltage has the opposite polarity, the silver ions are ionized and migrate back into the Ag₂S electrode, which means that an operating state with a high nonreactive resistance is again obtained.

An important aspect of the invention can therefore be seen in the reproducible production of an adjustable tunnel spacing between two electrically conductive regions (for example two electrodes).

Preferred developments of the invention can be found in the dependent claims.

In the method for producing a memory cell, the prescribed distance between the first and second electrically conductive regions can be formed by producing an auxiliary structure of prescribed thickness on the first electrically conductive region and removing the auxiliary structure after the second electrically conductive region is formed. An auxiliary or sacrificial structure of a prescribable thickness can thus be used to stipulate and set the geometry of the subsequently produced cavity accurately. Expressed another way, the auxiliary structure serves as a spacer between the electrically conductive regions.

Preferably, the auxiliary structure used is a self-assembled monolayer, as described in Haag et al., for example. A self-assembled monolayer may be, by way of example, an organic molecule comprising a carbon chain of adjustable length and a sulfur ion linked thereto. If the gold/sulfur coupling, which is particularly beneficial in terms of the coupling chemistry, for example, is used then the self-assembled monolayer's sulfur ion can be coupled to one of the electrically conductive regions, which means that the two electrically conductive regions can be arranged from one another at a distance in the nanometer range. Since, in particular, the length of the carbon chain can be adjusted more or less arbitrarily, it is possible to define the distance between the two electrically conductive regions using self-assembled monolayers as far as an accuracy in the angstrom range and below. After the second electrically conductive region has been produced on the self-assembled monolayer, the self-assembled monolayer can be removed using a selective etching method, which produces the cavity. The use of self-assembled monolayers (SAMs), which can also be called self-organizing monolayers, allows a defined distance between the two electrically conductive regions to be prescribed to an accuracy of 100 μm and below, with a high level of reproducibility.

As an alternative to using a self-assembled monolayer, the auxiliary or sacrificial structure can be produced using an atomic layer deposition method (ALD method). This method allows the defined deposition of a layer with a thickness which can be adjusted down to the accuracy of an atomic layer, i.e. down to an accuracy of a few angstroms.

Alternatively, the auxiliary structure may be produced using a molecular beam epitaxy method (MBE method).

The prescribed distance between the two electrically conductive regions is preferably between approximately 0.5 nm and approximately 5 nm, and with further preference between approximately 0.6 nm and approximately 2 nm. Such distances allow a bridging structure to form or regress sufficiently quickly, which means that fast programming and erasure times are achieved.

The inventive method allows the first electrically conductive region to be produced as a first interconnect, and the second electrically conductive region to be produced as a second interconnect, which interconnects can be produced so as to run at right angles to one another. Clearly, the crossover region for a first and a second interconnect, isolated by the tunnel contact, forms a memory cell based on the invention.

The text below describes the inventive memory cell in more detail. Refinements of the method for producing a memory cell also apply to the memory cell, and vice versa.

In the case of the inventive memory cell, the substrate may be a semiconductor substrate, preferably a silicon substrate such as a silicon wafer or a silicon chip.

The first or the second electrically conductive region (particularly that electrically conductive region from which a bridging structure can grow to the other electrically conductive region) can comprise a solid-state electrolyte, a glass comprising metal ions, a semiconductor comprising metal ions or a chalcogenide. A chalcogenide can be understood to be a material which comprises an element from the sixth main group in the periodic table of the elements, particularly sulfur, selenium and/or tellurium. Preferably, the first or the second electrically conductive region comprises a chalcogenide material and a metal material. The chalcogenide material can be selected from the group comprising arsenic, germanium, selenium, tellurium, bismuth, nickel, sulfur, polonium and zinc. The metal material can be selected from the first or second main group in the periodic table of the elements, with silver, copper or zinc being preferred.

By way of example, the first or the second electrically conductive region may comprise silver sulfide, or alternatively arsenic sulfide, germanium sulfide or germanium selenide.

The first or the second electrically conductive region (particularly that electrically conductive region to which a bridging structure can grow from the other electrically conductive region) may comprise metallic material, such as silver, gold, aluminum and/or platinum.

Of particular advantage is a material combination in which one of the electrically conductive regions is produced from gold material, silver material or copper material, and the auxiliary structure used is a self-assembled monolayer with a sulfur end group. In this case, it is possible to use the beneficial gold/sulfur coupling chemistry, which also acts with the materials silver and copper in similar fashion.

The text below gives a more detailed description of the inventive memory cell arrangement containing inventive memory cells. Refinements of the memory cell also apply to the memory cell arrangement comprising memory cells.

The memory cells may be arranged essentially in matrix form. By way of example, first interconnects can be produced as first electrically conductive regions in a first direction and second interconnects can be produced as second electrical conductive regions in a second direction. Each crossover region between one of the first interconnects and one of the second interconnects may then contain a memory cell based on the invention if the first or second interconnects are arranged from one another at a distance which corresponds to a tunnel spacing.

For at least some of the memory cells in the memory cell arrangement, selection elements for selecting a memory cell may be produced in and/or on the substrate. The selection elements are preferably field effect transistors, and with further preference vertical field effect transistors. The selection elements may be used as switching elements, which means that it is possible to detect the flow of current through a memory cell selected by applying an electrical voltage to the gate region of a field effect transistor and therefore to read the information content stored therein.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A and 1B illustrate experimentation arrangements based on the prior art.

FIG. 2 illustrates a graph illustrating a voltage/resistance characteristic for the experimentation arrangements shown in FIG. 1.

FIGS. 3A to 3D illustrate layer sequences at different times during a method for producing a memory cell in line with a preferred exemplary embodiment of a invention.

FIG. 4 illustrates a memory cell arrangement in line with a preferred exemplary embodiment of the invention.

FIG. 5 illustrates a memory cell in line with a preferred exemplary embodiment of the invention.

FIG. 6 illustrates a memory cell in line with another preferred exemplary embodiment of the invention.

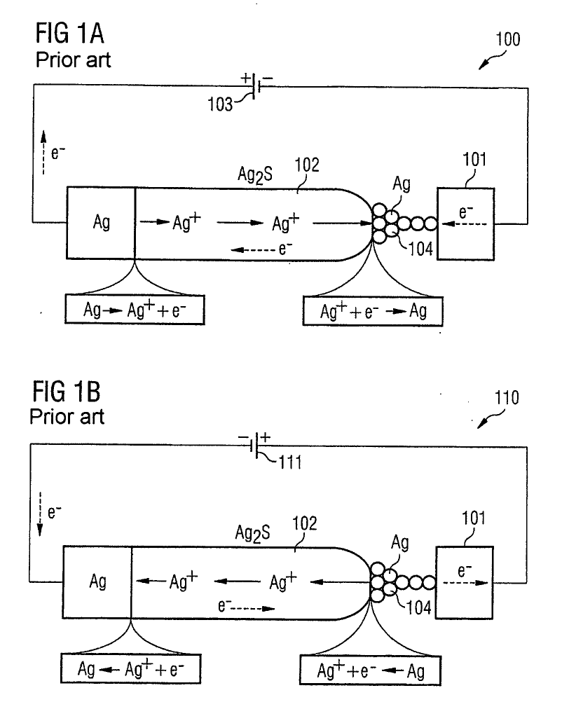

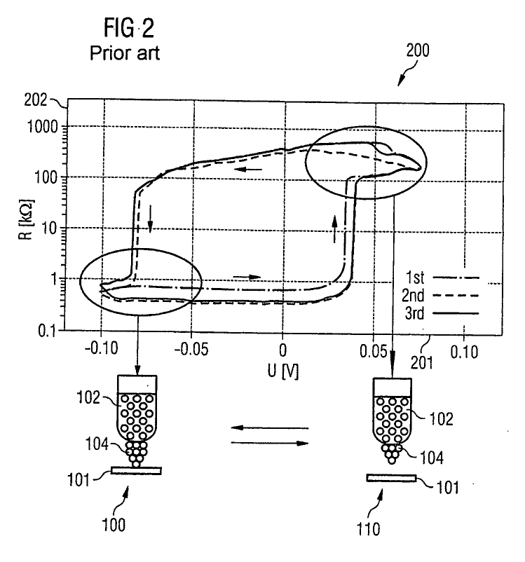

Components which are the same or similar in different figures have been provided with the same reference numerals.

The illustrations in the figures are schematic and not to scale.

### DETAILED DESCRIPTION

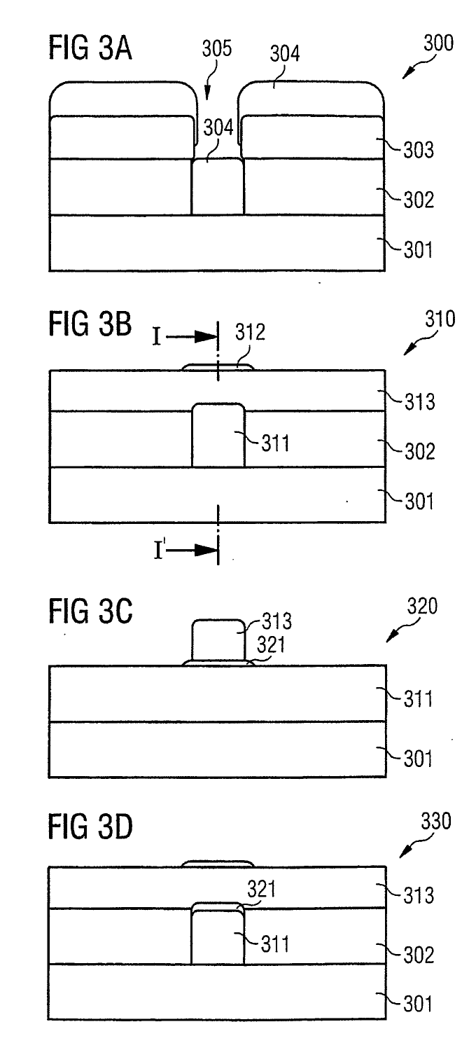

The text below refers to FIG. 3A to FIG. 3D to describe a method for producing a memory cell in line with the preferred exemplary embodiment of the invention.

To obtain the layer sequence 300 shown in FIG. 3A, a silicon oxide layer 302 (which is approximately 100 nm thick in this exemplary embodiment) is deposited onto a silicon substrate 301 in which evaluation or switching electronics (for example amplifiers, selection transistors etc.) may already have been produced beforehand. A photoresist layer 303 is deposited onto the silicon oxide layer 302. Using a lithography method and a dry-etching method, a trench 305 is made in the silicon oxide layer 302 or in the photoresist layer 303. After the etching, the material of the photoresist layer 303 is not incinerated, but rather is subjected to a wet-etching step using buffered hydrofluoric acid (HF), such that slight underetching of the photoresist 303 is obtained. Next, a directional vapor deposition or sputtering method is used to deposit a titanium layer which is approximately 10 nm thick in the trench 305 (not shown in the figure). Gold material 304 is then deposited up to a prescribed thickness, which is chosen such that the trench 305 made in the silicon oxide layer 302 is just filled. This also deposits gold material 304 onto the surface of the photoresist 303.

To obtain the layer sequence 310 shown in FIG. 3B, a liftoff method is used to remove material of the photoresist 303 and of the share of the gold material 304 which is produced thereon, so that a gold electrode 311 remains in the trench 305. The layer sequence obtained in this manner is subjected to treatment in H₂ or O₂ plasma. Next, an SAM layer (self-assembled monolayer) 312 of a prescribed thickness (i.e., molecular length) is put onto the gold electrode 311. The SAM layer 312 comprises molecules which have a carbon chain whose one end portion holds a group containing sulfur. This sulfur group can dock on the gold material of the gold electrode 311 in defined fashion, so that the SAM layer 312 is produced in the manner shown in FIG. 3B with good physical location. By selecting the length of the molecules in the SAM layer 312, it is possible to set the thickness of the subsequently produced tunnel cavity exactly. When the SAM layer 312 has been deposited, the resultant layer sequence is covered with a germanium sulfide layer which is approximately 10 nm thick, and is then sputtered with a silver layer which is approximately 1 nm to 5 nm thick. The resultant layer sequence is subjected to UV radiation, which drives silver ions into the germanium sulfide layer. The resultant layer sequence can be sputtered again with gold, silver or platinum in order to increase the electrical conductivity or the mechanical robustness of the top layer. Optionally, an additional silver sulfide layer which is approximately 10 nm thick can be vapor deposited and possibly reinforced. This results in the chalcogenide electrode 313 produced on the SAM layer 312.

The text below describes how the layer sequence 320 shown in FIG. 3C is obtained. It should first be noted that the views in FIG. 3A, FIG. 3B, FIG. 3D are cross-sectional views which are different than the cross-sectional view in FIG. 3C. FIG. 3C shows a development of the layer sequence 310 which is shown in FIG. 3B, taken along a sectional line I-I′ which is shown in FIG. 3B.

To obtain the layer sequence 320 shown in FIG. 3C, the chalcogenide electrode 313 is patterned to form an interconnect. This is done using a further resist mask (not shown in the figure) and subsequent dry etching. This exposes the SAM layer 312. The SAM layer 312 is then removed using a solvent and a temperature increase with possibly subsequent hydrogen plasma treatment, which forms the material-free tunnel contact or cavity 321.

The layer sequence 320 is a memory cell in line with a preferred exemplary embodiment of the invention.

FIG. 3D illustrates the memory cell from FIG. 3C in a view which corresponds to that shown in FIG. 3A and FIG. 3B.

It should be noted that the memory cell shown in FIG. 3C and FIG. 3D can be covered with silicon oxide produced using a plasma method. The arrangement obtained can be planarized, e.g. using a CMP (“Chemical Mechanical Polishing”) method. A further layer of memory cells can then be produced on the memory cell or memory cell arrangement which has been made. This allows large scale 3D integration.

The text below refers to FIG. 3D to explain the functionality of the memory cell stored there.

A description will first be given of how information can be programmed into the memory cell. If a positive electrical potential is applied to the chalcogenide electrode 313 and a negative electrical potential is applied to the gold electrode 311 then a silver bridging structure grows from the chalcogenide electrode 313 and bridges the cavity 321 (which is a few nanometers thick) between the gold electrode 311 and the chalcogenide electrode 313. If the value of the electrical current is now measured for a reading voltage between the electrodes 311, 313, it will be high on account of the low-resistance configuration caused by bridging the cavity 321 with the bridging structure. If the polarity of the previously applied voltage between the electrodes 311, 313 is reversed, so that the positive potential is applied to the gold electrode 311, then the dendrite or the bridging structure regresses, so that the cavity 321 forms a tunnel spacing between electrodes 311, 313. The flow of current when the reading voltage is applied is now smaller than in the case in which a bridging structure is formed.

The operating states “high nonreactive resistance” or “low nonreactive resistance” can be identified by the logic values “1” and “0” (or vice versa), for example. The memory information is thus clearly coded in the respective value of a memory cell's nonreactive resistance.

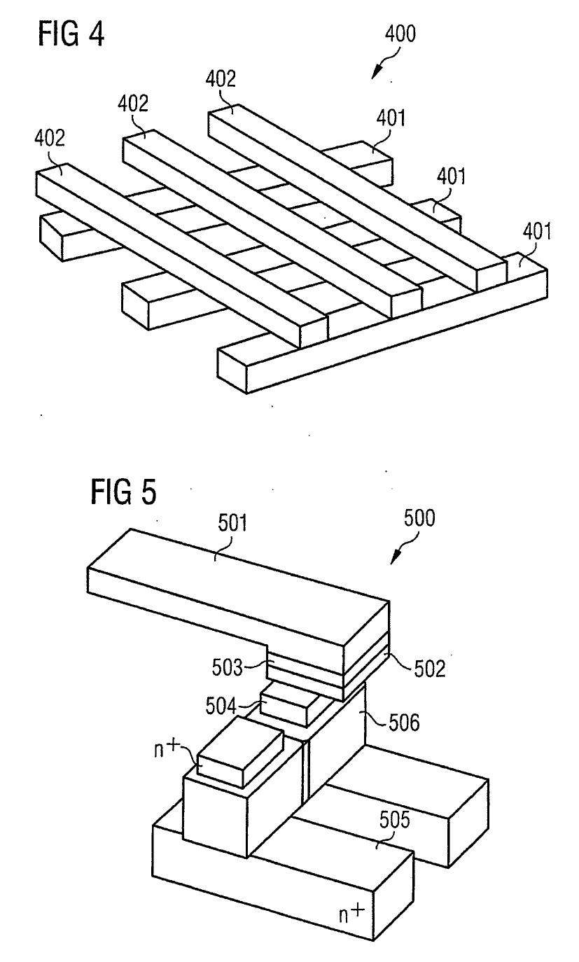

The text below refers to FIG. 4 to describe a memory cell arrangement 400 in line with a preferred exemplary embodiment of the invention.

The memory cell arrangement 400 is formed from a multiplicity of gold bit lines 401 running in a first direction and from a multiplicity of chalcogenide word lines 402 (comprising silver sulfide) running essentially at right angles thereto. Each crossover region between a gold bit line 401 and a chalcogenide word line 402 contains a cavity (not shown in FIG. 4) which forms a memory cell of the invention together with adjoining regions of the associated gold bit line 401 and of the associated chalcogenide word line 402. The cavities in the crossover regions between gold bit lines 401 and chalcogenide word lines 402 are in turn formed by removing a previously applied SAM (self-assembled monolayer) layer.

The text below refers to FIG. 5 to describe a memory cell 500 in line with a preferred exemplary embodiment of the invention.

The memory cell shown in FIG. 5 has a first electrode 501 and a second electrode 502, between which electrodes 501, 502 a cavity 503 is formed. The first and second electrodes 501, 502 are set up such that upon application of a first voltage between the electrodes 501, 502 a structure which bridges the cavity 503 is formed from material from one of the electrodes 501, 502. In addition, the two electrodes 501, 502 are set up such that upon application of a second voltage, whose polarity is opposite to that of the first voltage, between the electrodes 501, 502 material from a structure which bridges the cavity 503 between the electrodes 501, 502 is taken back, which electrically decouples the electrodes 501, 502 from one another over the cavity.

In other words, for a fixed voltage between the electrodes 501, 502, the value of the electrical current is dependent on whether or not the cavity 503 is bridged by a bridging structure. Components 501 to 503 thus form the core region of the memory cell 500, with a multiplicity of memory cells 500 being able to be arranged in a memory cell arrangement in a similar manner to the one shown in FIG. 4, for example. In this case, it is necessary to be able to write the memory information to a particular memory cell, or to read it therefrom, in defined fashion. This is done using a vertical field effect transistor in the exemplary embodiment shown in FIG. 5. To be precise, FIG. 5 shows two vertical field effect transistors, one of which is associated with the components 501 to 503. The other field effect transistor, which is of similar design to the field effect transistor associated with the components 501 to 503, can be used to couple to another memory cell.

The second electrode 502 is coupled to a first source/drain region 504 in the vertical field effect transistor. Arranged between the first source/drain region 504 and a second source/drain region 505 is a channel region (not shown in FIG. 5) of the vertical field effect transistor. The channel region is surrounded by a surrounded gate 506, with the surrounded gate 506 being decoupled from the channel region by means of a gate-insulating region (not shown).

The text below explains the functionality of the memory cell 500. If the cavity 503 between the electrodes 501, 503 is bridged in a first operating state, the arrangement of components 501 to 503 has a low value for the nonreactive resistance. The application of a voltage to the surrounded gate region 506 makes the channel region conductive on account of the field effect, and a flow of electric current between the source/drain regions 504, 505 is possible. When a fixed voltage is applied between the first electrode 501 and the second source/drain region 505, the value of the electrical current which flows is a measure of whether or not the cavity 503 is bridged by a bridging structure. The value of the electrical current is thus higher in the scenario described than in a complementary scenario in which the cavity 503 is free of any bridging structure. In other words, by applying an electrical potential to the surrounded gate region 506 and a potential between the first electrode 501 and the second source/drain region 505 it is possible to read the memory cell.

By applying a sufficiently high electrical voltage of prescribable polarity between the first electrode 501 and the second gate region 505, a bridging structure can be grown or taken back in the cavity 503.

It should be noted that the inventive memory cell is not limited to two electrodes.

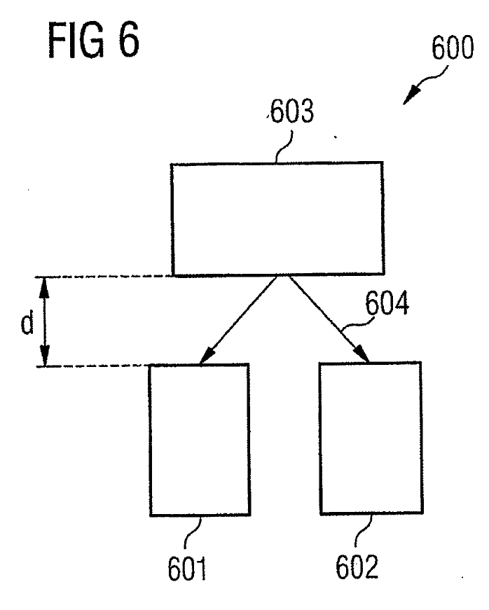

FIG. 6 illustrates a memory cell 600 in line with another exemplary embodiment of the invention, in which a first chalcogenide electrode 601 and a second chalcogenide electrode 602 are provided. In addition, a silver electrode 603 is arranged at a prescribed distance “d” from the chalcogenide electrodes 601, 602. By applying a suitable voltage between at least one of the chalcogenide electrodes 601, 602 and the silver electrodes 603, it is possible to grow a bridging structure 604 jointly starting from the chalcogenide electrodes 601, 602, in order to produce coupling to the silver electrode 603.

Accordingly, arbitrarily more complicated arrangements of electrodes are possible, because it is possible to produce reversible coupling selectively, for example just between electrodes 601 and electrodes 603 or just between electrodes 602 and 603. This means that couplings can be formed and removed again in circuits reversibly at microelectronic level.

It should also be noted that the inventive memory cell may also be used as a logic element, with logic being able to be written to an appropriate logic element reversibly.

1.-19. (canceled)

20. A method for producing a binary information memory cell comprising:
producing a first electrically conductive region associated with a substrate;
producing an auxiliary structure of a prescribed thickness on the first electrically conductive region;
producing a second electrically conductive region on the auxiliary structure; removing the auxiliary structure after the second electrically conductive region has been produced, so that a cavity is formed between the first electrically conductive region and the second electrically conductive region, the distance between the first electrically conductive region and the second electrically conductive region corresponding to a tunnel spacing; and
configuring the first and second electrically conductive regions such that upon applying a first voltage to the first and second electrically conductive regions a structure which at least partially bridges the distance between the first and second electrically conductive regions is formed from material from at least one of the electrically conductive regions.

21. The method of claim 20, comprising wherein applying a second voltage to the electrically conductive regions, material from the structure which at least partially bridges the distance between the electrically conductive regions is taken back.

22. The method of claim 20, comprising:
defining the auxiliary structure to be a self-assembled monolayer.

23. The method of claim 20, comprising:
producing the auxiliary structure using an atomic layer deposition method.

24. The method of claim 20, comprising:
producing the auxiliary structure using a molecular beam epitaxy method.

25. The method of claim 20, comprising:
defining the distance between the first conductive region and the second conductive region to be 0.5 nm and 5 nm.

26. The method of claim 20, comprising:
defining the distance between the first conductive region and the second conductive region to be between 0.6 nm and 2 nm.

27. The method of claim 20, comprising:
in which the first electrically conductive region is a first interconnect and the second electrically conductive region is a second interconnect, which interconnects are produced so as to run toward one another at substantially right angles.

28. The method of claim 20, comprising:
defining the substrate to be a silicon substrate.

29. The method of claim 20, comprising:
forming the first electrically conductive region or the second electrically conductive region from at least one material from a group consisting of a solid-state electrolyte, a glass comprising metal ions, a semiconductor comprising metal ions, or a chalcogenide.

30. The method of claim 20, comprising:
forming the first electrically conductive region or the second electrically conductive region from silver sulfide.

31. The method of claim 20, comprising:
forming the first electrically conductive region or the second electrically conductive region from metal material.

32. The method of claim 20, comprising:
forming the first electrically conductive region or the second electrically conductive region from at least one material from a group consisting of silver, copper, aluminum, gold and/or platinum.

33. A binary information memory cell comprising:
a substrate;
a first electrically conductive region associated with the substrate;
a second electrically conductive region arranged at a prescribable distance from the first electrically conductive region such that a cavity is formed between the first and second electrically conductive regions; and
wherein the first and second electrically conductive regions are set up such that upon application of a first voltage to the electrically conductive regions a structure which at least partially bridges the distance between the electrically conductive regions is formed in freely growing fashion from material from at least one of the electrically conductive regions; and upon application of a second voltage to the electrically conductive regions material from a structure which at least partially bridges the distance between the electrically conductive regions is taken back.

34. The memory cell of claim 33, comprising wherein the first or the second electrically conductive region is made of metallic material.

35. The memory cell of claim 33, comprising wherein the first or the second electrically conductive region is made of at least one material from a group consisting of silver, copper, aluminum, gold and/or platinum.

36. A binary information memory cell arrangement comprising:
a plurality of binary information memory cells having one or more memory cells comprising:
a substrate;
a first electrically conductive region associated with the substrate;
a second electrically conductive region arranged at a prescribable distance from the first electrically conductive region such that a cavity is formed between the first and second electrically conductive regions; and
wherein the first and second electrically conductive regions are set up such that upon application of a first voltage to the electrically conductive regions a structure which at least partially bridges the distance between the electrically conductive regions is formed in freely growing fashion from material from at least one of the electrically conductive regions; and upon application of a second voltage to the electrically conductive regions material from a structure which at least partially bridges the distance between the electrically conductive regions is taken back.

37. The binary information memory cell arrangement of claim 36, comprising wherein the binary information memory cells are arranged in matrix form.

38. The binary information memory cell arrangement of claim 36, in which selection elements for selecting a binary information memory cell are produced in and/or on the substrate for at least some of the binary information memory cells.

39. The binary information memory cell arrangement as claimed in claim 38, in which the selection elements are field effect transistors.

40. The binary information memory cell arrangement as claimed in claim 39, in which the selection elements are vertical field effect transistors.

41. A binary information memory cell comprising:
a substrate;
a first electrically conductive means associated with the substrate;
a second electrically conductive means arranged at a prescribable distance from the first electrically conductive means such that a cavity is formed between the first and second electrically conductive means; and
wherein the first and second electrically conductive means are set up such that upon application of a first voltage to the electrically conductive means a structure which at least partially bridges the distance between the electrically conductive means is formed in freely growing fashion from material from at least one of the electrically conductive means; and upon application of a second voltage to the electrically conductive means material from a structure which at least partially bridges the distance between the electrically conductive regions is taken back.
